(19) United States
(12) Patent Application Publication
(10) Pub. No.: US 2015/0084036 A1
(43) Pub. Date: Mar. 26, 2015

(54) THIN FILM TRANSISTOR AND FABRICATING METHOD THEREOF

(71) Applicant: Au Optronics Corporation, Hsinchu (TW)

(72) Inventor: Chih-Pang Chang, Taipei City (TW)

(21) Appl. No.: 14/300,246

(22) Filed: Jun. 10, 2014

(30) Foreign Application Priority Data
Sep. 23, 2013 (TW) 102134085

(51) Int. Cl. H01L 33/26; H01L 33/00

(52) U.S. Cl. CPC H01L 33/26; H01L 33/005
USPC 257/43; 438/46

(57) ABSTRACT

A TFT and a fabricating method thereof are provided. The TFT includes an oxide semiconductor layer, a gate insulating layer, a gate, an oxygen-absorbing layer, an insulating layer, and conductive electrodes. The oxide semiconductor layer includes low-oxygen regions and a channel region between the low-oxygen regions. The gate insulating layer is disposed between the oxide semiconductor layer and the gate, and covers the channel region and exposes the low-oxygen regions. The oxygen-absorbing layer having first openings is disposed on the low-oxygen regions each having a first area exposed by the first opening. The insulating layer having second openings covers the oxygen-absorbing layer, the oxide semiconductor layer, and the gate. The low-oxygen region having a second area is exposed by the second opening within the first opening. The second area is smaller than the first area. The conductive electrodes in the second openings are in contact with the low-oxygen regions.

### CROSS-REFERENCE TO RELATED APPLICATION

This application claims the priority benefit of Taiwan application serial no. 102134085, filed on Sep. 23, 2013. The entirety of the above-mentioned patent application is hereby incorporated by reference herein and made a part of this specification.

### BACKGROUND OF THE INVENTION

1. Field of the Invention

The invention relates to a semiconductor device and a fabricating method thereof, and particularly relates to a thin film transistor and a fabricating method thereof.

2. Description of Related Art

With the progress of modern information technology, displays of various specifications have been widely adopted in display screens of consumers' electronic products, such as cell phones, notebook computers, digital cameras, and personal digital assistants (PDAs), etc. Among the displays, LCD (liquid crystal display) and OELD (organic electro-luminescent display, or called OLED) become predominant in the market owing to the advantages of light weight, small volume, and low power consumption. Fabricating processes of LCD and OLED include arranging an array of semiconductor devices on a substrate. The semiconductor devices include thin film transistors (TFT).

TFT is becoming smaller in size as the resolution of displays improves. Now a TFT with self-align top-gate structure has been developed to overcome the limitation of alignment of the photolithography process and improve the gate-drain and gate-source parasitic capacitance (i.e. Cgd and Cgs). According to the current technology utilizing the oxide semiconductor (indium gallium zinc oxide, IGZO) as the channel material, a sputter-formed aluminum thin film on the entire surface is required with the thickness of the aluminum thin film controlled at about 5 nm and annealing that causes oxidation of the aluminum thin film by the high-resistance indium gallium zinc oxide (IGZO) is needed to form a low-resistance IGZO. However, the current technology faces the problem that the conductive electrodes formed in the contact window may come in contact with the aluminum oxide or aluminum that is not completely oxidized at the lateral side of the contact window, which easily results in higher current leakage and causes device failure.

### SUMMARY OF THE INVENTION

The invention provides a thin film transistor and a fabricating method thereof for fabricating a self-align top-gate thin film transistor with better device characteristics.

The invention provides a thin film transistor disposed on a substrate. The thin film transistor includes an oxide semiconductor layer, a gate insulating layer, a gate, an oxygen-absorbing layer, an insulating layer, and a plurality of conductive electrodes. The oxide semiconductor layer is disposed on the substrate and includes a channel region and a plurality of low-oxygen regions, wherein the channel region is located between the low-oxygen regions. The gate insulating layer covers the channel region and exposes the low-oxygen regions. The gate insulating layer is located between the oxide semiconductor layer and the gate. The oxygen-absorbing layer is disposed on the low-oxygen regions of the oxide semiconductor layer and has a plurality of first openings. Each of the first openings exposes a first area of one of the low-oxygen regions. The insulating layer covers the oxygen-absorbing layer, the oxide semiconductor layer, and the gate. Moreover, the insulating layer has a plurality of second openings. Each of the second openings is located in one of the first openings to expose a second area of the corresponding one of the low-oxygen regions, wherein the second area is smaller than the first area. The conductive electrodes are respectively disposed in the second openings to be in contact with the low-oxygen regions having the second area.

The invention further provides a fabricating method of a thin film transistor, and the fabricating method includes the following steps. An oxide semiconductor layer is formed on a substrate and includes a channel region and a plurality of low-oxygen regions, wherein the channel region is located between the low-oxygen regions. A gate insulating layer is formed on the substrate and covers the channel region of the oxide semiconductor layer. A gate is formed on the substrate, and the gate insulating layer is located between the gate and the oxide semiconductor layer. An oxygen-absorbing layer is formed on the substrate to be in contact with the low-oxygen regions of the oxide semiconductor layer. A plurality of first openings is formed in the oxygen-absorbing layer, and each of the first openings exposes a first area of one of the low-oxygen regions. An insulating layer is formed on the substrate and covers the oxygen-absorbing layer, the oxide semiconductor layer, and the gate. A plurality of second openings is formed in the insulating layer. Each of the second openings is located in one of the first openings to expose a second area of the corresponding one of the low-oxygen regions having a second area, wherein the second area is smaller than the first area. A plurality of conductive electrodes is in the second openings.

Based on the above, according to the thin film transistor and the fabricating method of the invention, the oxygen-absorbing layer is formed with the first openings while the insulating layer is formed with the second openings, and the second openings are located in the first openings. Moreover, the conductive electrodes are disposed in the second openings to be in contact with the low-oxygen regions but not in contact with the oxygen-absorbing layer. Thus, the insulating layer of the invention is disposed between the conductive electrodes and the oxygen-absorbing layer to prevent contact therebetween and for electrical insulation. Accordingly, the design according to the embodiments prevents the conductive electrodes from contacting the oxygen-absorbing material (e.g. aluminum oxide or aluminum that is not completely oxidized) in the oxygen-absorbing layer at the lateral side, thereby improving current leakage, so that the thin film transistor performs better device characteristics.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic cross-sectional view of a thin film transistor according to the first embodiment of the invention.

FIG. 2 is a schematic top view of a region A of FIG. 1.

FIGS. 3A to 3D are schematic cross-sectional views illustrating a fabricating method of the thin film transistor according to the first embodiment of the invention.

FIG. 4 is a schematic cross-sectional view of a thin film transistor according to the second embodiment of the invention.

FIG. 5 is a graph illustrating Ids-Vgs (drain current-gate voltage) curves of a thin film transistor of a comparative example.

FIG. 6 is a graph illustrating Ids-Vgs (drain current-gate voltage) curves of a thin film transistor of an experimental example.

### DESCRIPTION OF THE EMBODIMENTS

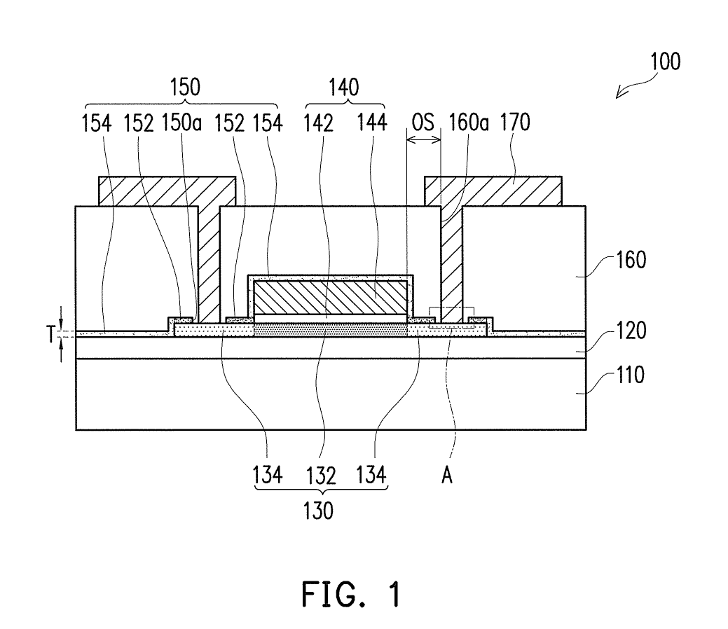

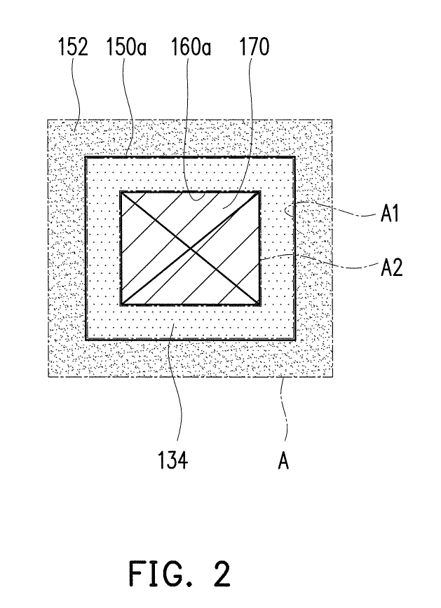

FIG. 1 is a schematic cross-sectional view of a thin film transistor 100 according to the first embodiment of the invention. FIG. 2 is a schematic top view of a region A of FIG. 1, wherein the region A refers to the region of one of first openings.

The thin film transistor 100 is disposed on a substrate 110. A material of the substrate 110 is glass, quartz, organic polymer, or metal, etc., for example. Moreover, in this embodiment, a buffer layer 120 is disposed between the thin film transistor 100 and the substrate 110. That is to say, the substrate 110 may have the buffer layer 120 disposed thereon. A material of the buffer layer 120 is an oxide, for example. Nevertheless, the invention should not be construed as limited thereto. Other embodiments of the invention may not include the buffer layer 120 as long as the substrate 110 is able to sustain a photolithography and etch process carried out in a fabricating method of the thin film transistor 100.

With reference to FIG. 1 and FIG. 2, the thin film transistor 100 includes an oxide semiconductor layer 130, a gate insulating layer 142, a gate 144, an oxygen-absorbing layer 150, an insulating layer 160, and a plurality of conductive electrodes 170.

The oxide semiconductor layer 130 is disposed on the buffer layer 120. The oxide semiconductor layer 130 is formed using a metal oxide semiconductor material, for example, and the metal oxide semiconductor material includes IGZO or other suitable materials. The oxide semiconductor layer 130 includes a channel region 132 and a plurality of low-oxygen regions 134, wherein the channel region 132 is located between two adjacent low-oxygen regions 134. Moreover, an oxygen concentration of the low-oxygen regions 134 of the oxide semiconductor layer 130 is lower than an oxygen concentration of the channel region 132.

The gate insulating layer 142 covers the channel region 132 but exposes the low-oxygen regions 134. A material of the gate insulating layer 142 is silicon oxide, silicon nitride, silicon oxy-nitride, or other suitable insulating materials, for example. In addition, the gate 144 is disposed on the gate insulating layer 142. That is to say, the gate insulating layer 142 is located between the oxide semiconductor layer 130 and the gate 144. A material of the gate 144 includes metal, metal oxide, organic conductive material, or a combination of the foregoing. The gate 144 and the gate insulating layer 142 together form an island structure 140, which is disposed on the channel region 132 of the oxide semiconductor layer 130. In this embodiment, a width of the gate 144 roughly approximates to a width of the gate insulating layer 142; however, the invention is not limited thereto. In some other embodiments of the invention, the width of the gate 144 may be less than the width of the gate insulating layer 142.

The oxygen-absorbing layer 150 is disposed on the low-oxygen regions 134 of the oxide semiconductor layer 130 and has a plurality of first openings 150a. Each of the first openings 150a exposes a first area A1 of one of the low-oxygen regions 134 (as shown in FIG. 2, the region A refers to the region includes one of the first openings 150a.). In addition, in this embodiment, the oxygen-absorbing layer 150 conformally covers the island structure 140 and can further extend outside the oxide semiconductor layer 130. In other words, the oxygen-absorbing layer 150 may include a first portion 152 and at least one second portion 154, wherein the first portion 152 is in contact with the low-oxygen region 134 of the oxide semiconductor layer 130, and the second portion 154 is not in contact with the oxide semiconductor layer 130. Herein, the second portion 154 is in contact with the gate 144, the gate insulating layer 142, or the buffer layer 120. The first portion 152 has a first oxygen concentration and the second portion 154 has a second oxygen concentration, wherein the first oxygen concentration is higher than the second oxygen concentration. A material of the oxygen-absorbing layer 150 includes magnesium, aluminum, silicon, titanium, vanadium, chromium, nickel, yttrium, zirconium, niobium, molybdenum, cerium, neodymium, hafnium, tantalum, tungsten, or a combination of the foregoing; however, the invention is not limited thereto. In some other embodiments of the invention, the oxygen-absorbing layer 150 may be formed using other suitable oxygen-absorbing materials as long as the oxygen-absorbing material can absorb oxygen from the low-oxygen regions 134 to form the desired low-resistance low-oxygen regions 134. A thickness T of the oxygen-absorbing layer 150 ranges 2 nm to 20 nm, for example, and preferably 4 nm to 10 nm.

The insulating layer 160 is disposed on the oxygen-absorbing layer 150, and a portion of the insulating layer 160 is disposed in the first openings 150a. A material of the insulating layer 160 is silicon oxide, silicon nitride, silicon oxy-nitride, or other suitable insulating materials, for example. More specifically, the insulating layer 160 covers the oxygen-absorbing layer 150, the oxide semiconductor layer 130, and the gate 144. Moreover, the insulating layer 160 has a plurality of second openings 160a. Each of the second openings 160a is located in one of the first openings 150a to expose a second area A2 of the corresponding one of the low-oxygen regions 134, wherein the second area A2 is smaller than the first area A1.

The conductive electrodes 170 are respectively disposed in the second openings 160a to be in contact with the portion of the low-oxygen regions 134 having the second area A2. A material of the conductive electrodes 170 includes metal, metal oxide, organic conductive material, or a combination of the foregoing. Moreover, a length OS of FIG. 1 represents the length from a boundary of the channel region 132 to a boundary of the conductive electrode 170 (source/drain), and the oxide semiconductor layer 130 at this region is a part of the low-resistance region 134.

It is worth mentioning that the oxygen-absorbing layer 150 and the conductive electrodes 170 are separated by the insulating layer 160. More specifically, a portion of the insulating layer 160 is disposed in the first openings 150a and located between the conductive electrodes 170 (located in the second openings 160a) and the oxygen-absorbing layer 150 (located in regions outside the first openings 150a) to prevent contact therebetween and for electrical insulation. Accordingly, the embodiment prevents the conductive electrodes 170 from contacting the oxygen-absorbing material (e.g. aluminum oxide or aluminum that is not completely oxidized) in the oxygen-absorbing layer 150 at the lateral side via the second openings 160a (i.e. contact window openings), thereby improving current leakage, so that the thin film transistor 100 performs better device characteristics.

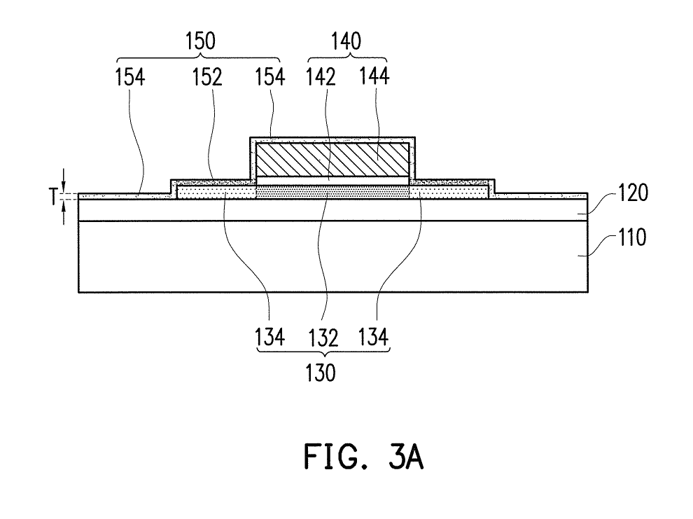

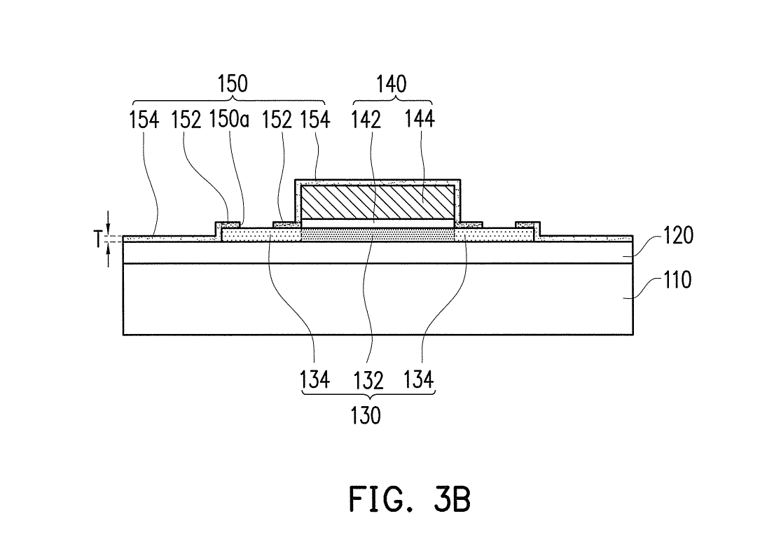

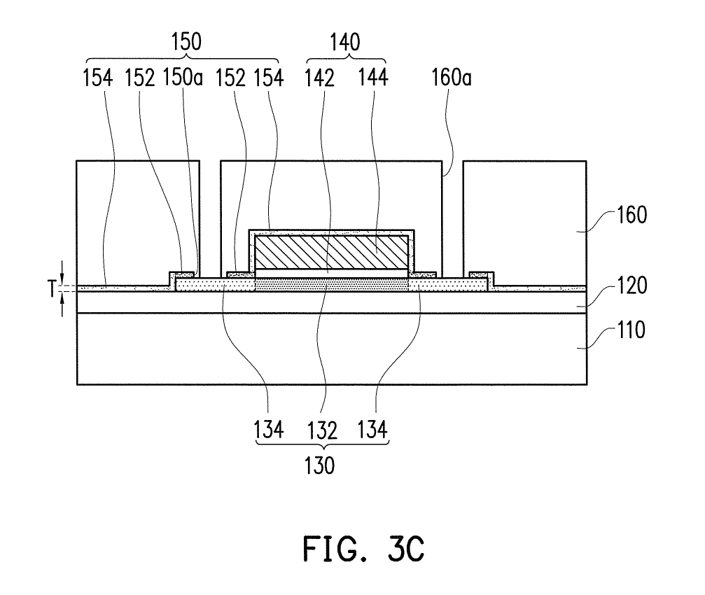

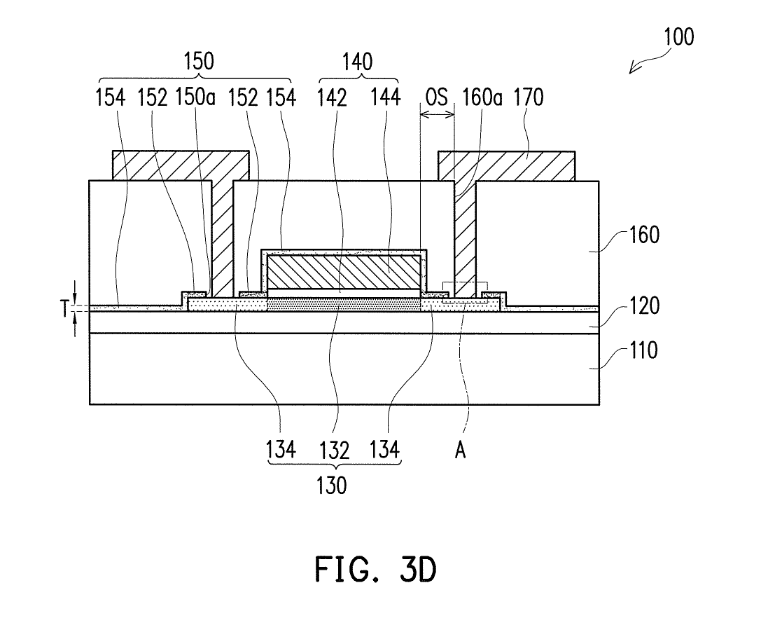

The fabricating method of the thin film transistor 100 is described in detail below. FIGS. 3A to 3D are schematic cross-sectional views illustrating the fabricating method of the thin film transistor 100 according to the first embodiment of the invention.

Referring to FIG. 3A, first, the buffer layer 120 is formed on the substrate 110 to cover an entire surface of the substrate 110. Next, the oxide semiconductor layer 130 is formed on the buffer layer 120. A method for forming the oxide semiconductor layer 130 includes forming an oxide semiconductor material layer (not shown) on the buffer layer 120, and then patterning the oxide semiconductor material layer to form the oxide semiconductor layer 130. The patterning is performed by using a photolithography and etch process or other suitable methods. Moreover, the oxide semiconductor layer 130 includes the channel region 132 and the plurality of low-oxygen regions 134, wherein the channel region 132 is located between two adjacent low-oxygen regions 134.

Following that, the gate insulating layer 142 and the gate 144 are formed on the oxide semiconductor layer 130. The gate 144 and the gate insulating layer 142 together form the island structure 140, which is disposed on the channel region 132 of the oxide semiconductor layer 130. To be more specific, the gate insulating layer 142 covers the channel region 132 of the oxide semiconductor layer 130, and is located between the gate 144 and the oxide semiconductor layer 130. A method for forming the gate insulating layer 142 and the gate 144 includes forming an insulating material layer (not shown) and a conductive layer (not shown) in sequence on the oxide semiconductor layer 130 and the buffer layer 120, and then patterning the conductive layer and the insulating material layer to form the gate 144 and the gate insulating layer 142. The patterning is performed by using a photolithography and etch process or other suitable methods. In this embodiment, the gate insulating layer 142 and the gate 144 are formed in the same patterning process; however, the invention is not limited thereto. In some other embodiments of the invention, the gate insulating layer 142 and the gate 144 may be formed in different patterning processes, such that the width of the gate 144 is less than the width of the gate insulating layer 142.

Next, with reference to FIG. 3A, the oxygen-absorbing layer 150 is formed on the substrate 110 to be at least in contact with the low-oxygen regions 134 of the oxide semiconductor layer 130. In this embodiment, a method for forming the oxygen-absorbing layer 150 includes disposing an oxygen-absorbing material (not shown) on the substrate 110 in a way that at least a portion of the oxygen-absorbing material is in contact with the oxide semiconductor layer 130. Then, an annealing process is carried out to cause the oxygen-absorbing material to absorb oxygen from the oxide semiconductor layer 130, so as to form the low-oxygen regions 134. Thus, the oxygen-absorbing layer 150 has the first portion 152 having the first oxygen concentration and the second portion 154 having the second oxygen concentration, wherein the first oxygen concentration is higher than the second oxygen concentration. Moreover, the first portion 152 is in direct contact with the oxide semiconductor layer 130 while the second portion 154 is not in contact with the oxide semiconductor layer 130.

Thereafter, with reference to FIG. 3B, the plurality of first openings 150a are formed in the first portion 152 of the oxygen-absorbing layer 150, wherein each of the first openings 150a exposes a first area A1 of one of the low-oxygen regions 134. A method for forming the first openings 150a includes absorbing the oxygen of the low-oxygen regions 134 by the oxygen-absorbing layer 150 to make the oxygen concentration of the low-oxygen regions 134 lower than the oxygen concentration of the channel region 132, and then performing a patterning process to remove a portion of the oxygen-absorbing layer 150 to form the first openings 150a. The patterning is performed by using a photolithography and etch process or other suitable methods.

Then, with reference to FIG. 3C, the insulating layer 160 is formed on the substrate 110 to cover the oxygen-absorbing layer 150, the oxide semiconductor layer 130, and the gate 144. In this embodiment, a method for forming the insulating layer 160 includes disposing an insulating material (not shown) on the oxygen-absorbing layer 150 to fill the first openings 150a. Thereafter, the plurality of second openings 160a are formed in the insulating layer 160. Each of the second openings 160a is located in one of the first openings 150a to expose a second area A2 of the corresponding one of the low-oxygen regions 134 having the second area A2, wherein the second area A2 is smaller than the first area A1. A method for forming the second openings 160a includes performing a patterning process to remove a portion of the insulating layer 160, so as to form the second openings 160a. The patterning is performed by using a photolithography and etch process or other suitable methods.

It is worth mentioning that, in an embodiment of the invention, the first openings 150a and the second openings 160a may be formed using the same mask (not shown) in different patterning processes. Therefore, it is not required to prepare an additional mask and the production costs are reduced. In order to differentiate the sizes of the first openings 150a and the second openings 160a, conditions of the two patterning processes, such as exposure intensity, thickness of photoresist, and depth of etching, etc., may be different. Nevertheless, the invention should not be construed as limited thereto. In some other embodiments of the invention, different masks (not shown) may be used to form the first openings 150a and the second openings 160a respectively.

Next, referring to FIG. 3D, the plurality of conductive electrodes 170 are at least formed in the second openings 160a. In this embodiment, a method for forming the conductive electrodes 170 includes disposing a conductive electrode material (not shown) on the insulating layer 160 to fill the second openings 160a, and then patterning the conductive electrode material on the insulating layer 160. The patterning is performed by using a photolithography and etch process or other suitable methods.

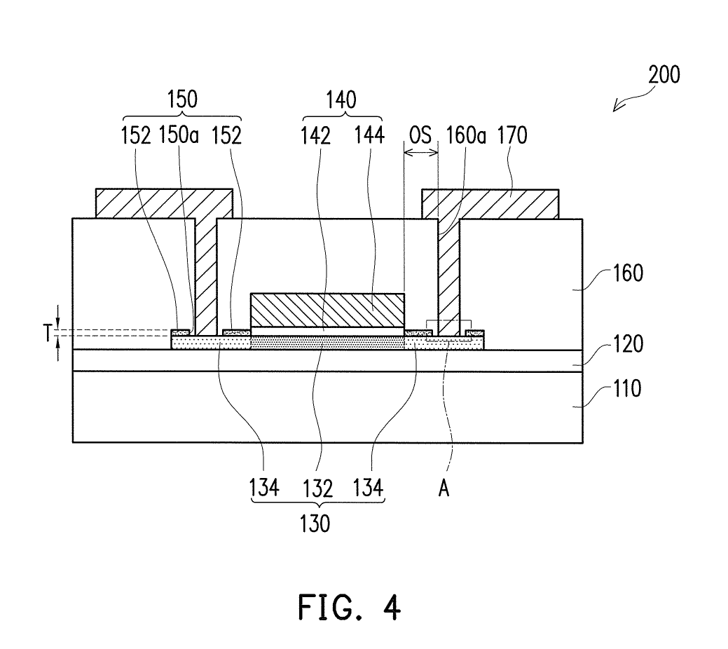

FIG. 4 is a schematic cross-sectional view of a thin film transistor 200 according to the second embodiment of the invention. The embodiment of FIG. 4 is similar to the embodiment of FIG. 1. Therefore, elements identical to those of FIG. 1 are denoted with the same reference numerals in FIG. 4, which will not be described again hereinafter. With reference to FIG. 4, a difference between the embodiment of FIG. 4 and the embodiment of FIG. 1 lies in that the oxygen-absorbing layer 150 merely includes the first portion 152 and does not include the second portion 154.

A fabricating method of the thin film transistor 200 is similar to the fabricating method of the thin film transistor 100. Thus, the following paragraphs only elaborate the difference therebetween. Compared with the fabricating method of the thin film transistor 100, the fabricating method of the thin film transistor 200 further includes a step of removing the second portion 154 (i.e. a portion of the oxygen-absorbing layer 150 which is not in contact with the low-oxygen regions 134) of the oxygen-absorbing layer 150 in FIG. 3A. For instance, when performing the patterning process to remove a portion of the oxygen-absorbing layer 150 to form the first openings 150a (as shown in FIG. 3B), the patterning process may simultaneously remove the second portion 154 of the oxygen-absorbing layer 150. Nevertheless, it should be noted that the invention is not limited thereto. In some other embodiments of the invention, an additional process may be carried out to remove the second portion 154 of the oxygen-absorbing layer 150 before or after the formation of the first openings 150a.

Moreover, if the oxygen-absorbing material used to form the oxygen-absorbing layer 150 is aluminum, a material of the first portion 152 is aluminum oxide and a material of the second portion 154 is aluminum, for example. Thus, the second portion 154 shown in FIG. 3A can be removed by selecting appropriate etching solutions according to the selectivity of aluminum oxide and aluminum, and then performing a wet etching process to remove the second portion 154.

Device characteristics provided by the design of a self-align top-gate thin film transistor of the invention are described below. Particularly, the structure of the thin film transistor 100 of FIG. 1 is used in the comparative example, but the oxygen-absorbing layer therein is in contact with the conductive electrodes. The structure of the thin film transistor 100 of FIG. 1 is also used in the experimental example, wherein the oxygen-absorbing layer 150 and the conductive electrodes 170 are separated by the insulating layer 160.

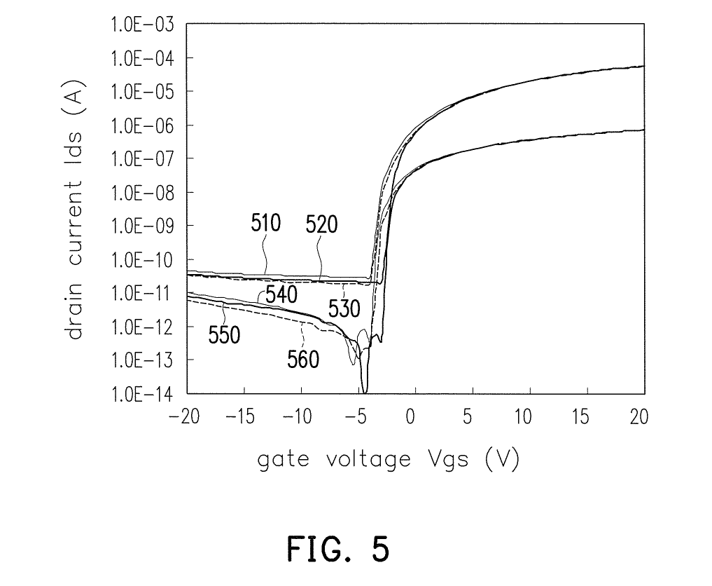

FIG. 5 is a graph illustrating Ids-Vgs (drain current-gate voltage) curves of the thin film transistor of the comparative example. In FIG. 5, the channel width and length of the thin film transistor represented by the curves 510-560 are both 5 micrometers; the drain voltage (Vd) of the thin film transistor represented by the curves 510-530 is 10 volts; and the drain voltage of the thin film transistor represented by the curves 540-560 is 0.1 volt. In addition, the length OS of one single side of the oxide semiconductor layer of the thin film transistor represented by the curves 510 and 540 is 1 micrometer; the length OS of one single side of the oxide semiconductor layer of the thin film transistor represented by the curves 520 and 550 is 1.5 micrometers; and the length OS of one single side of the oxide semiconductor layer of the thin film transistor represented by the curves 530 and 560 is 2 micrometers. The length OS of one single side represents the length from a boundary of the channel region to a boundary of the conductive electrode (source/drain), and the oxide semiconductor layer at this region is a low-resistance region. It is known from FIG. 5 that the drain current is higher (about 1.0E-10 amp to 1.0E-13 amp) when the gate voltage is negative, and therefore, the structure of the thin film transistor of the comparative example has the problem of higher current leakage.

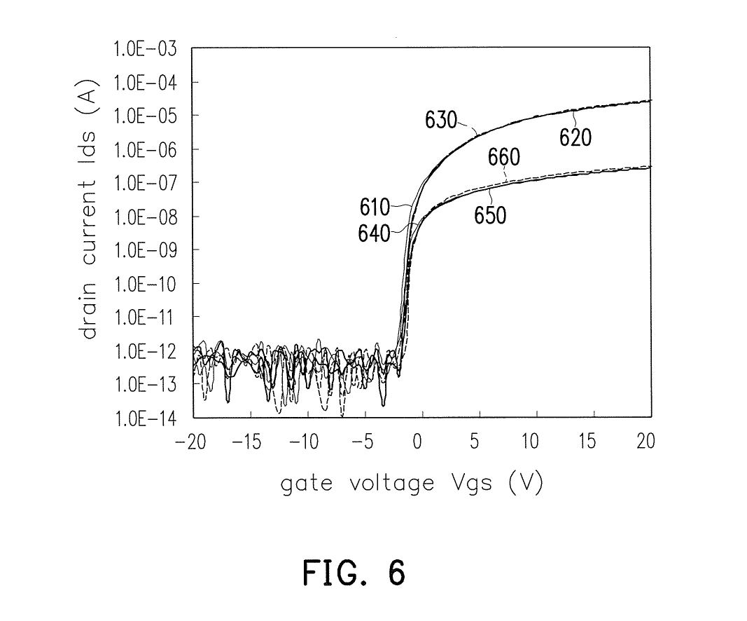

FIG. 6 is a graph illustrating Ids-Vgs (drain current-gate voltage) curves of the thin film transistor of the experimental example. In FIG. 6, the channel width and length of the thin film transistor represented by the curves 610-660 are both 5 micrometers; the drain voltage of the thin film transistor represented by the curves 610-630 is 10 volts; and the drain voltage of the thin film transistor represented by the curves 640-660 is 0.1 volt. In addition, the length OS of one single side of the oxide semiconductor layer of the thin film transistor represented by the curves 610 and 640 is 1 micrometer; the length OS of one single side of the oxide semiconductor layer of the thin film transistor represented by the curves 620 and 650 is 1.5 micrometers; and the length OS of one single side of the oxide semiconductor layer of the thin film transistor represented by the curves 630 and 660 is 2 micrometers. It is known from FIG. 6 that the drain current is very low (about 1.0E-12 amp to 1.0E-14 amp, which reaches a detection limit of the machine, as shown by the noise of FIG. 6) when the gate voltage is negative. Based on the comparison, because the oxygen-absorbing layer 150 and the conductive electrodes 170 are separated by the insulating layer 160, the structure of the thin film transistor 100 of the embodiment according to the invention has improved current leakage and better device characteristics.

To conclude the above, according to the thin film transistor and the fabricating method of the invention, the first openings of the oxygen-absorbing layer expose a first area of one of the low-oxygen regions, and the second openings of the insulating layer are located in the first openings to expose a second area of the corresponding one of the low-oxygen regions, wherein the second area is smaller than the first area. In other words, the oxygen-absorbing layer can be disposed in the region outside the first openings while the insulating layer can be disposed in the region outside the second openings, and the second openings are in the first openings. Moreover, the conductive electrodes are disposed in the second openings to be in contact with the second area of the low-oxygen regions. Thus, the insulating layer of the embodiment according to the invention is disposed between the conductive electrodes (located in the second openings) and the oxygen-absorbing layer (located in regions outside the first openings) to prevent contact therebetween and for electrical insulation. Accordingly, the embodiment according to the invention prevents the conductive electrodes from contacting the oxygen-absorbing material (e.g. aluminum oxide or aluminum that is not completely oxidized) in the oxygen-absorbing layer at the lateral side via the second openings (i.e. contact window openings), thereby improving current leakage, so that the thin film transistor performs better device characteristics.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

What is claimed is:

1. A thin film transistor disposed on a substrate, the thin film transistor comprising:
an oxide semiconductor layer disposed on the substrate and comprising a channel region and a plurality of low-oxygen regions, wherein the channel region is located between the low-oxygen regions;
a gate insulating layer covering the channel region and exposing the low-oxygen regions;
a gate, wherein the gate insulating layer is located between the oxide semiconductor layer and the gate;
an oxygen-absorbing layer disposed on the low-oxygen regions of the oxide semiconductor layer and comprising a plurality of first openings each exposing a first area of one of the low-oxygen regions;
an insulating layer disposed on the substrate and covering the oxygen-absorbing layer, the oxide semiconductor layer, and the gate, wherein the insulating layer comprises a plurality of second openings each located in one of the first openings to expose a second area of the corresponding one of the low-oxygen regions, and the second area is smaller than the first area; and
a plurality of conductive electrodes respectively disposed in the second openings to be in contact with the low-oxygen regions having the second areas.

2. The thin film transistor according to claim 1, wherein a material of the oxygen-absorbing layer comprises magnesium, aluminum, silicon, titanium, vanadium, chromium, nickel, yttrium, zirconium, niobium, molybdenum, cerium, neodymium, hafnium, tantalum, tungsten, or a combination of the above.

3. The thin film transistor according to claim 1, wherein a first portion of the oxygen-absorbing layer has a first oxygen concentration, and the first portion is in contact with the oxide semiconductor layer.

4. The thin film transistor according to claim 3, wherein the oxygen-absorbing layer further comprises a second portion that has a second oxygen concentration, and the first oxygen concentration is higher than the second oxygen concentration.

5. The thin film transistor according to claim 1, wherein the oxygen-absorbing layer covers the gate and further extends outside the oxide semiconductor layer.

6. The thin film transistor according to claim 1, wherein a thickness of the oxygen-absorbing layer is 2 nm to 20 nm.

7. The thin film transistor according to claim 1, wherein the thickness of the oxygen-absorbing layer is 4 nm to 10 nm.

8. The thin film transistor according to claim 1, wherein the oxygen-absorbing layer and the conductive electrodes are separated by the insulating layer.

9. The thin film transistor according to claim 1, wherein an oxygen concentration of the low-oxygen regions of the oxide semiconductor layer is lower than an oxygen concentration of the channel region.

10. The thin film transistor according to claim 1, wherein the gate and the gate insulating layer together form an island structure located on the channel region of the oxide semiconductor layer.

11. The thin film transistor according to claim 1, wherein a material of the conductive electrodes comprises metal, metal oxide, organic conductive material, or a combination of the above.

12. A fabricating method of a thin film transistor, the fabricating method comprising:
forming an oxide semiconductor layer on a substrate, wherein the oxide semiconductor layer comprises a channel region and a plurality of low-oxygen regions, and the channel region is located between the low-oxygen regions;
forming a gate insulating layer on the substrate to cover the channel region of the oxide semiconductor layer;
forming a gate on the substrate, wherein the gate insulating layer is located between the gate and the oxide semiconductor layer;
forming an oxygen-absorbing layer on the substrate to be in contact with the low-oxygen regions of the oxide semiconductor layer;
forming a plurality of first openings in the oxygen-absorbing layer, wherein each of the first openings exposes a first area of one of the low-oxygen regions;
forming an insulating layer on the substrate to cover the oxygen-absorbing layer, the oxide semiconductor layer, and the gate;
forming a plurality of second openings in the insulating layer, wherein each of the second openings is located in one of the first openings to expose a second of the corresponding one of the low-oxygen regions, and the second area is smaller than the first area; and
forming a plurality of conductive electrodes in the second openings.

13. The fabricating method according to claim 12, wherein a forming method of the oxygen-absorbing layer comprises disposing an oxygen-absorbing material on the substrate to be in contact with the low-oxygen regions of the oxide semiconductor layer to absorb oxygen of the low-oxygen regions.

14. The fabricating method according to claim 13, wherein a forming method of the first openings comprises performing a patterning step to remove a portion of the oxygen-absorbing layer to form the first openings after absorbing the oxygen of the low-oxygen regions to make an oxygen concentration of the low-oxygen regions lower than an oxygen concentration of the channel region.

15. The fabricating method according to claim 14, wherein the patterning step further comprises removing a portion of the oxygen-absorbing layer that is not in contact with the low-oxygen regions.

16. The fabricating method according to claim 13, wherein the oxygen-absorbing material comprises magnesium, aluminum, silicon, titanium, vanadium, chromium, nickel, yttrium, zirconium, niobium, molybdenum, cerium, neodymium, hafnium, tantalum, tungsten, or a combination of the above.

17. The fabricating method according to claim 12, wherein the first openings and the second openings are formed using the same mask.

18. The fabricating method according to claim 17, wherein the first openings and the second openings are formed by different patterning steps.

19. The fabricating method according to claim 12, wherein the first openings and the second openings are formed respectively using different masks.

20. The fabricating method according to claim 12, wherein a forming method of the gate insulating layer and the gate comprises disposing an insulating material layer and a conductive layer in sequence on the oxide semiconductor layer, and patterning the insulating material layer and the conductive layer to form the gate and the gate insulating layer.

21. The fabricating method according to claim 20, wherein the gate and the gate insulating layer together form an island structure located on the channel region of the oxide semiconductor layer.
